(19) United States
(12) Patent Application Publication
(10) Pub. No.: US 2009/0004887 A1
(43) Pub. Date: Jan. 1, 2009

(54) APPARATUS AND METHOD FOR DEPOSITION OF PROTECTIVE FILM FOR ORGANIC ELECTROLUMINESCENCE

(75) Inventors: Masayasu Suzuki, Hadano-shi (JP); Tetsuya Saruwatari, Hiratsuka-shi (JP)

Correspondence Address: RANKIN, HILL & CLARK LLP, 38210 Glenn Avenue, WILLOUGHBY, OH, 44094-7808, US

(73) Assignee: SHIMADZU CORPORATION, Kyoto-shi (JP)

(21) Appl. No.: 12/199,285

(22) Filed: Aug. 27, 2008

Related U.S. Application Data
(62) Division of application No. 10/833,675, filed on Apr. 28, 2004.

(30) Foreign Application Priority Data
Apr. 30, 2003 (JP) 2003-125056

(51) Int. Cl. H01L 21/31

(52) U.S. Cl. 438/792; 257/E21.24

(57) ABSTRACT

In a film deposition apparatus which deposition a film through SWP-CVD, a substrate holder on which a substrate is to be placed is provided with cooling means, thereby inhibiting occurrence of an increase in the temperature of the substrate, which would otherwise be caused during deposition of a film. A coolant passage is formed in the substrate holder, and coolant delivered from a chiller is circulated through the coolant passage, thereby cooling the substrate holder. Further, grooves are formed in the surface of a cooling holder where a substrate is to be placed, and the substrate is cooled by a helium gas by causing the helium gas to flow through the grooves.

### BACKGROUND OF THE INVENTION

1. Field of the Invention

The present invention relates to an apparatus and method for growing a protective film for organic electroluminescence (EL) by means of surface wave plasma CVD, as well as to an organic EL system.

2. Description of the Related Art

Recently, a display device of self-luminous type which displays an image by means of an organic compound; that is, a display element utilizing so-called organic electroluminescence (hereinafter called “organic EL”), has been at issue. The organic EL display element is superior to a conventional liquid-crystal display device in some points. More specifically, unlike the liquid-crystal display device, the organic EL display device can display the image without use of backlight due to its self-luminous characteristics. Further, the organic EL display device has a very simple structure whereby the display device can be made to be thin, compact, and light-weight. Moreover, thanks to its little power consumption, the organic EL display device is suitable for use as a display device of small information equipment, such as a portable cellular phone.

The basic configuration of the organic EL device is realized by forming an organic EL layer on a transparent glass substrate on which a transparent electrode is formed from indium-tin-oxide (ITO), and forming a metal electrode layer on the organic EL layer. The organic compound, such as triphenyldiamine, is used for the organic EL layer. Such an organic compound suffers a problem of reacting very readily with moisture or oxygen, which ends up being a display failure and shortens the life of the organic EL device.

Therefore, the configuration in which the organic EL layer is sealed by covering the organic EL layer with a damp-proof polymer film, and forming a silicon oxide film (SiOₓ) or a silicon nitride film (SiNₓ) on the organic EL layer. It can be said that the silicon nitride film is especially suitable for a protective film against moisture or oxygen because the higher the proportion of Si₃N₄ in the silicon nitride film, the more dense the film, and the silicon EL film becomes superior as the protective film. As for manufacturing methods for growing the silicon nitride film, RF plasma CVD or ECR-CVD is generally used as disclosed in JP-A-10-261487.

When an attempt is made to form a high-density silicon nitride film having a high proportion of Si₃N₄ by means of RF plasma CVD, the temperature of a substrate must be high enough for growing a film, for instance, 300° C. or higher. Such high temperature, however, is not recommended from the technical viewpoint of thermal damage that might be made to the organic EL layer, therefore the film should be grown at more lower temperature (of, e.g., 80° C. or less). However, in such a low temperature case, the dense silicon nitride film, such as already mentioned above, cannot be formed by means of RF plasma CVD. Turning to the ECR-CVD being adopted, plasma density becomes higher than the density of RF plasma, which allows a high-density silicon nitride film to be formed at a comparatively low temperature, however, in the ECR-CVD method, it is too difficult to dispose a large size substrate to be processed.

The high-density silicon nitride film also has a drawback of high internal stress. As mentioned previously, the metal electrode layer is formed on the organic EL layer. The organic EL layer, however, is not a film mechanically durable so that it becomes an unstable structure as if the metal electrode layer is floated above the organic EL layer in case of thinking about its conceptual image. Therefore, if the silicon nitride film is formed with involving high internal stress therein, the metal electrode layer might be isolated by such internal stress, whereby the silicon nitride film might be exfoliated.

The present invention is provided with an apparatus and a method for growing SiNₓ film without inflicting thermal damage on an organic EL device.

### SUMMARY OF THE INVENTION

A film deposition apparatus according to the first aspect of this invention is characterized by comprising: microwave generation means; a process chamber having a dielectric window; microwave transmission means which guides a microwave generated by the microwave generation means to the dielectric window, to thereby radiate the microwave into the process chamber; and cooling means for cooling a substrate having an organic EL device formed thereon, wherein a film deposition gas is dissociated and excited by surface wave plasma generated by emission of the microwave into the process chamber while the substrate is being cooled by the cooling means, thereby forming a silicon nitride film serving as a protective film on the organic EL device through the effect of surface wave plasma (SWP) CVD.

The second aspect of this invention is characterized by the film deposition apparatus of claim 1, in which the film deposition gas is formed from a first gas which includes at least nitrogen and produces radicals in plasma and a second gas including a silane gas; and that the gas supply means has a first supply section for supplying the first gas to the process chamber and a second supply section for supplying the second gas to a position that is closer to the substrate than to a point where the first gas is supplied.

The third aspect of this invention is characterized by a method for manufacturing a protective film for organic EL through use of the film deposition apparatus of claim 2, in which the protective film is formed by means of alternately stacking a silicon nitride film which is grown by setting a concentration of a nitrogen gas in a film deposition gas to a first predetermined concentration and which possesses compressive stress, and another silicon nitride film which is grown by setting the concentration of the nitrogen gas in the film deposition gas to a second predetermined concentration and which possesses tensile stress.

### BRIEF DESCRIPTION OF THE DRAWINGS

FIG. 1 is a view showing an embodiment of a film deposition apparatus according to the present invention, showing a diagrammatic configuration of an SWP-CVD apparatus;

FIG. 2 is a view showing another example of a gas inlet system;

FIG. 3 is a perspective view showing details of dielectric members 30a, 30b;

FIG. 4 is a view showing the relationship between a flow rate of an N₂ gas flowing during deposition of a film and internal stress of a grown SiNₓ film;

FIG. 5 is a cross-sectional view showing a diagrammatic configuration of an organic EL device;

FIG. 6 is a view showing a result of measurement of transmittance of a high-density SiNₓ film grown by the SWP-CVD apparatus of the embodiment;

FIG. 7 is a cross-sectional view showing another example of a protective film 45; and

FIG. 8 is a view showing a second embodiment of the organic EL device.

### DESCRIPTION OF THE PREFERRED EMBODIMENTS

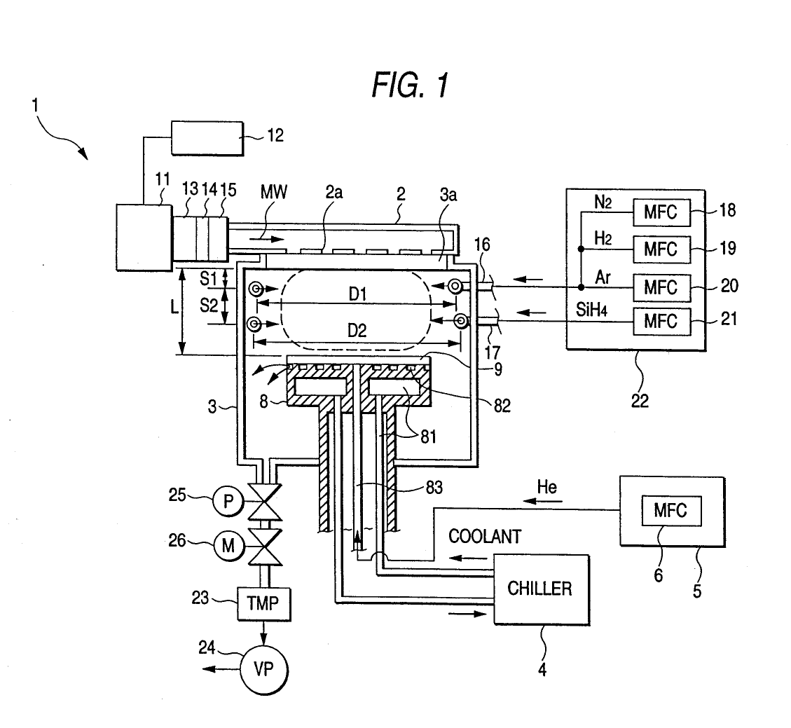

Embodiments of the invention will be described hereinbelow by reference to the drawings. FIG. 1 is a view showing a first embodiment of an apparatus for growing a film (hereinafter simply called “film deposition apparatus”) according to the invention, showing the basic configuration of an SWP-CVD (Surface Wave Plasma Chemical Vapor Deposition) apparatus for forming a SiNₓ film (silicon nitride film) by means of SWP-CVD. The SWP-CVD apparatus is equipped with a process chamber 3 for performing CVD; a microwave generation section 1 for generating a microwave of 2.45 GHz; and a waveguide 2 for transmitting the microwave to the process chamber 3.

Power is supplied from a microwave power source 12 to a microwave transmitter 11 provided in the microwave generation section 1. An isolator 13, a directional coupler 14, and a tuner 15 are interposed between the microwave transmitter 11 and the waveguide 2. A microwave MW generated by the microwave transmitter 11 is transmitted to the waveguide 2 by way of these devices. The process chamber 3 constitutes a vacuum chamber, and a portion of a partition wall is formed as a microwave inlet window 3a formed from a dielectric material such as quartz.

The microwave inlet window 3a may be rectangular or circular in shape. The waveguide 2 is provided at a position above the microwave inlet window 3a. A plurality of slot antennas 2a for radiating the microwave MW to the process chamber 3 are formed on the surface of the waveguide 2 that is opposed to the microwave inlet window 3a. More specifically, the surface might be a bottom surface of the waveguide 2.

A substrate holder 8 is provided in the process chamber 3, and a substrate 9 having an organic EL layer formed thereof is placed on top of the substrate holder 8. In the present embodiment, the substrate 9 is formed from a transparent glass substrate, and the organic EL layer is formed on the substrate 9. The substrate 9 is disposed to be opposed to the microwave inlet window 3a of the process chamber 3. Here, the substrate holder 8 can move in the vertical direction of the drawing.

A coolant channel 81 for circulating a coolant is formed within the substrate holder 8, and the coolant is supplied into the coolant channel 81 after having being cooled by a chiller 4. Further, helical grooves 82 are formed in the surface of the substrate holder 8 where the substrate is to be placed. A helium (He) gas is supplied to the groove 82 by way of a gas pipe 83. Reference numeral 5 designates a helium gas source for supplying the gas. The flow rate of supplied gas is controlled by a mass flow controller 6.

The coolant flowing through the coolant channel 81 cools the substrate holder 8, and the substrate holder 8 cools the He gas flowing through the grooves 82. This cooled He gas comes into direct contact with the back of the substrate 9 placed on the substrate holder 8, whereupon the substrate 9 is cooled. Specifically, the heat of the substrate 9 is transmitted to the coolant in the coolant channel 81 by way of the substrate holder 8 and the He gas. As mentioned above, the substrate 9 is cooled by way of the He gas so that the temperature of the substrate can be kept at a low level.

In the process chamber 3, at least two pipes are independently provided, one is a gas supply pipe 16 for supplying a nitrogen gas (N₂), a hydrogen gas (H₂), and an argon gas (Ar) to the inside of the process chamber 3, and the other is a gas supply pipe 17 for supplying a silane (SiH₄) gas. The N₂ gas, the H₂ gas, and the Ar gas are supplied to the gas supply pipe 16 from a gas supply source 22 by way of mass controllers 18, 19, and 20, respectively. On the other hand, an SiH₄ gas is supplied to the gas supply pipe 17 from the gas supply source 22 by way of a mass flow controller 21.

Each of the gas supply pipes 16, 17 is shaped in a ring shape so as to surround plasma P generated within the process chamber 3. A gas mixture consisting of the N₂, H₂, and Ar gases is uniformly injected from the gas supply pipe 16, while the SiH₄ gas is uniformly injected from the gas supply pipe 17 to a plasma region. Diameters D1, D2 of the ring-shaped gas supply pipes 16, 17 are set so as to become larger than those of the microwave inlet window 3a and to assume a relationship D2≧D1.

The inside of the process chamber 3 is evacuated by means of a turbo molecular pump (TMP) 23. A variable conductance valve 25 and a main valve 26 are provided between the process chamber 3 and the TMP 23. Conductance between the TMP 23 and the process chamber 3 is varied by means of the variable conductance valve, thereby changing a pumping speed of the process chamber 3. Reference numeral 24 denotes a back pump of the TMP 23, and an oil-sealed rotary vacuum pump RP or a dry vacuum pump DrP is used for the back pump 24 of the TMP 23.

When the microwave radiated from the slot antenna 2a in the waveguide 2 is incident into the process chamber 3 by way of the microwave inlet window 3a, the gas in the process chamber 3 is ionized and dissociated by the microwave, thereby generating plasma. When the electron density of plasma P has exceeded a microwave cutoff density, the microwave transmits, for a surface wave along the microwave inlet window 3a, thereby spreading over the whole area of the microwave inlet window 3a. Consequently, the density of the plasma P excited by the surface wave becomes high in the vicinity of the microwave inlet window 3a.

The N₂, H₂, and Ar gases supplied from the gas supply pipe 16 are dissociated and excited by the plasma P, thereby generating radicals. The SiH₄ gas injected from the gas supply pipe 17 downstream of the plasma P is dissociated and excited by the radicals, and Si and N bond to form the silicon nitride film (SiNₓ film) on the substrate 9.

A rate at which the SiNₓ film deposition is relying on the deposition rates of the processing gases (e.g., the SiH₄ gas and the N₂ gas) and the microwave power. The microwave power is supplied to the level where all the gas supplied for film deposition can be dissociated. However, if some limitation is placed on the supply of microwave power, the quantity of film processing gas might be controlled and supplied in accordance with the microwave power.

Since an optimum pressure range is known to be required during deposition of a film, the pumping speed of an exhaust system should be controlled so that the process pressure can be optimized in accordance with the quantity of the gas to be supplied for the film deposition. Briefly, said control can be performed by regulating the conductance of the variable conductance valve 25. The internal pressure of the process chamber 3 is monitored during a film deposition, and the variable conductance valve 25 is regulated so that the process pressure is optimum at all times, thereby enabling stable deposition of a high-density SiNₓ film.

In addition to the foregoing requirements, it is also necessary for the deposition of the SiNₓ film on the substrate 9 under the optimum conditions required to optimize a distance S1 from the microwave inlet window 3a to the gas supply pipe 16, a distance S2 from the gas supply pipe 16 to the gas supply pipe 17, and a distance L from the microwave inlet window 3a to the substrate 9. Dissociation of the SiH₄ gas is accelerated by utilization of the radicals generated in the plasma. In this regard, in relation to the distances S1 and S2, the gas supply pipe 16 is preferably disposed at a position closer to an opening section 4a than to the position where the gas supply pipe 17 is disposed (S1<S2). In the SWP-CVD apparatus shown in FIG. 1, the distance S1 is preferably set to a value from 30 mm to 100 mm.

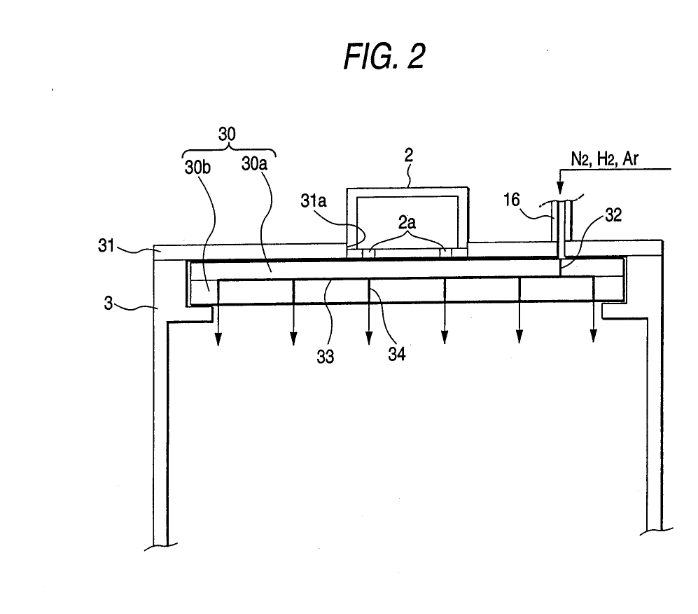

FIG. 2 is a view showing another example of a gas inlet system. FIG. 2 is a view of the film deposition apparatus when viewed in the direction in which the microwave transmits through the waveguide 2; that is, it is a view of the film deposition apparatus when viewed from the righthand side in FIG. 1. The waveguide 2 is provided so as to be inserted into an opening 31a formed in a flange 31 of the process chamber 3. A microwave inlet window 30 is constituted of two members; that is, an upper dielectric member 30a and a lower dielectric member 30b, and has gas flow channels 32, 33, and 34. In the apparatus shown in FIG. 2, the gas supply pipe 16 is provided in the flange 31 and remains in mutual communication with the gas flow channel 32 formed in the dielectric member 30a. Those supplied N₂, H₂, and Ar gases flow in the sequence of the gas flow channels 32, 33, and 34, which are injected into the inside of the process chamber 3 from a lower surface of the dielectric member 30b.

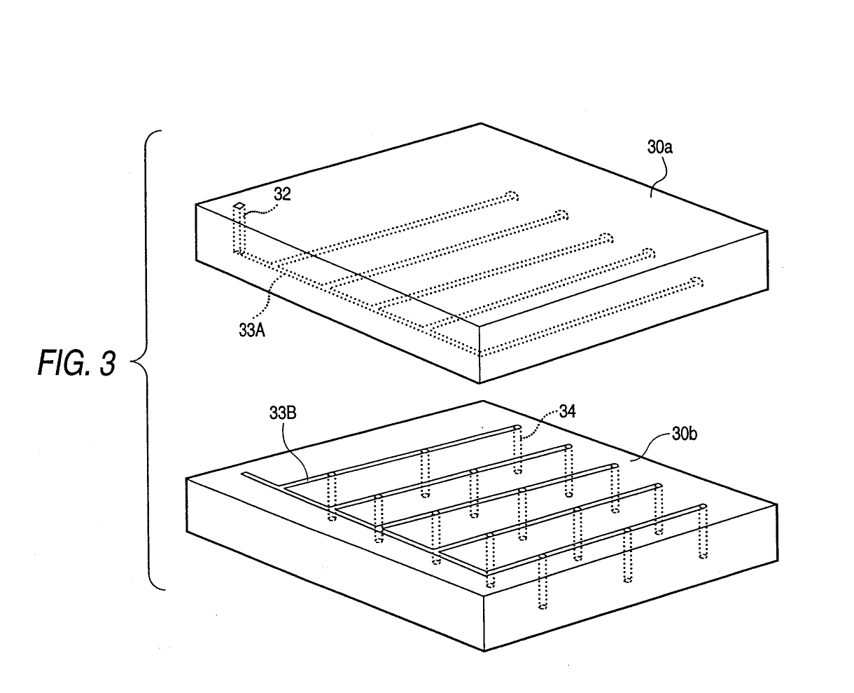

FIG. 3 is a perspective view showing details of the dielectric members 30a, 30b. In the dielectric member 30a, the gas flow channel 32 is a through hole which penetrates vertically through the dielectric member 30a to be communicated with a groove 33A that is formed in the lower surface of the dielectric member 30a. A groove 33B is formed in the upper surface of the dielectric member 30b. On the other hand, a plurality of holes, which penetrate from the groove 33B to the lower surface of the dielectric member 30b, are formed as the gas flow channels 34. The microwave inlet window 30 is formed in such a way that the lower surface of the dielectric member 30a remains in intimate contact with the upper surface of the dielectric member 30b. The grooves 33A, 33B are formed so as to oppose each other. When the dielectric members 30a, 30b are stacked one on top of the other, the grooves 33A, 33B constitute the gas flow channel 33.

The surface wave plasma P is formed so as to be opposed to almost the entire area of the underside of the microwave inlet window 30. As shown in FIG. 3, the gas flow channels 34 functioning as gas outlets might be formed uniformly over the entire underside of the dielectric member 30b so that a uniform film can be formed on the substrate 9.

SWP-CVD is known to generate plasma which is higher in density than that of being generated by RF plasma CVD or other CVD. The electron density produced in the vicinity of a substrate during SWP-CVD becomes in the range from 5×10⁹ to 10¹² (cm³), while electron temperature ranging from 1 to 20 (eV) or somewhere around it. Therefore, a high-density SiNₓ film can be formed without heating the substrate 9 through use of a heater or the like. The high-density SiNₓ film is a silicon nitride film including a large proportion of Si₃N₄ bond, whose characteristic might be such that the larger the proportion of Si₃N₄ bond, the higher the transparency of the silicon nitride film. Consequently, there can be formed a protective film having a superior moisture proofing characteristic. However, since the substrate 9 is faced up to high-density plasma, the present embodiment secures the temperature of the substrate 9 to be kept at a low temperature by cooling the substrate 9 with He gas.

### <<Cooling of the Substrate 9>>

In the embodiment, the grooves 82 are formed in the surface of the substrate holder 8, on which a substrate is to be placed (hereinafter called “substrate mount surface”), and it is preferable to feed He gas so as to flow into the grooves 82 as a heat transfer gas in order to cool down the substrate 9 effectively. For instance, if the surface of the substrate holder 8 is deemed as just a plane, the back surface of the substrate 9 seems to make the surface contact with the mount surface. In actually, however, it is a sort of the point contact that is made for said case between the back surface of the substrate and the mount surface therefore the substrate 9 becomes difficult for being cooled down sufficiently in spite of the effort of cooling the substrate holder 8 itself. To the contrary, in this embodiment, performance of heat transfer between the substrate holder 8 and the substrate 9 can be much more improved, by feeding the He gas to flow through the grooves 82, which realizes a high heat transfer efficiently.

For instance, if the flow rate of the He gas is taken a value of 1 (sccm) or thereabouts, then the pressure in the grooves 82 might fall within a pressure range of a viscous flow, where said He gas can be used as a coolant gas for the heat transfer purpose. The He gas supplied to the center of the grooves 82 flows toward a peripheral direction through the helical grooves 82 and is injected inside of the process chamber 3 as indicated by the arrow shown in FIG. 1. Therefore, the flow rate of the He gas should be set to a value which does not affect film deposition processes. However, as the above mentioned flow rate of 1 (sccm) may not pose such a problem.

Whether or not the He gas becomes the viscous flow in the grooves 82 is dependent on the cross-sectional area of the groove as well as on the flow rate of the He gas. Hence, the flow rate of an He gas shall be set to the level where it does not affect the film deposition processes, however, the cross-sectional area of the groove 82 shall be further adjusted while keeping said flow rate as it is so that the He gas becomes the viscous flow.

### <<Stress on SiNₓ Film>>

When the SiNₓ film deposition in SWP-CVD, the proportion of Si₃N₄ in the SiNₓ film can be controlled by means of changing the concentration of the N₂ gas ratio. Specifically, the high-density SiNₓ film having a high proportion of Si₃N₄ is formed by means of increasing the concentration of the nitrogen gas in the material gas. Conversely, decreasing the concentration of the N₂ gas results in formation of a low-density SiN, film having a low proportion of Si₃N₄.

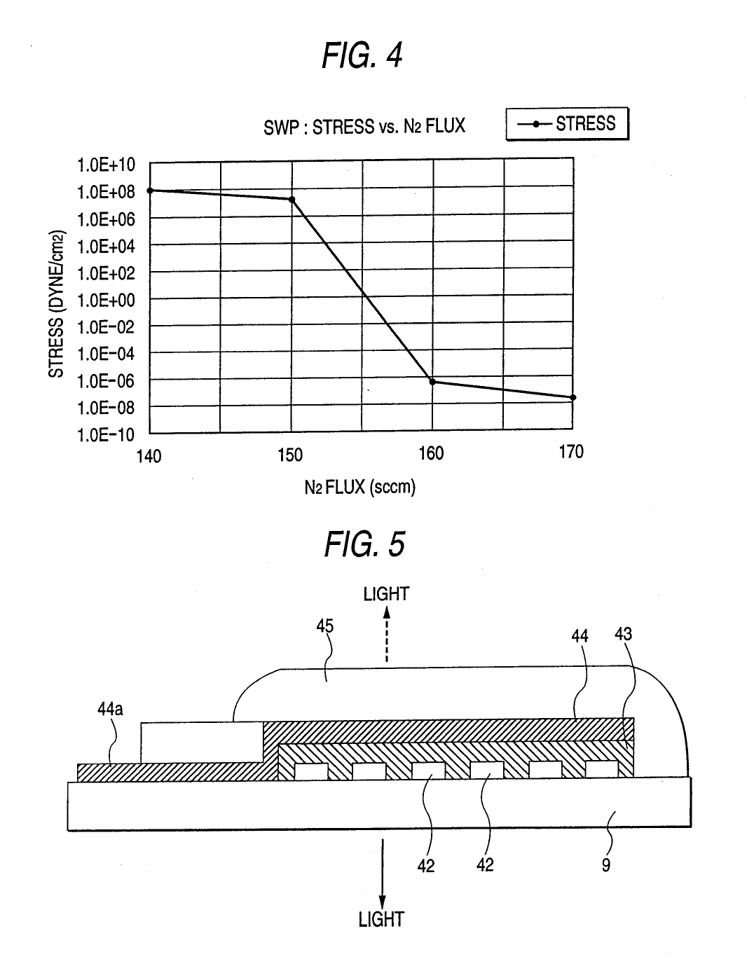

FIG. 4 is a view showing the relationship between the flow rate of the N₂ gas which is required to grow a film, and an internal stress exerted on said grown SiNₓ film. The vertical axis of FIG. 4 represents the internal stress, and the unit of the internal stress is (dyn/cm²). The positive value is meant that the internal stress is tensile stress, while a negative value is meant that, the internal stress is compressive stress. The horizontal axis of FIG. 4 shows a flow rate of the N₂ gas, and the unit of the flow rate is expressed as “sccm”. When the SiNₓ film is formed with various values of N₂ gas concentrations by changing the flow rate of the N₂ gas, the stresses exerted on such formed SiNₓ films vary according to the concentration of the N₂ gas. When the flow rate of the N₂ gas is decreased, the stress on the SiNₓ film can be seen to change from compressive stress to tensile stress at a boundary of a certain flow rate of the N₂ gas (i.e., a certain N₂ concentration).

The data shown in FIG. 4 relate to the SiNₓ film having a thickness of 0.5 (μm). Besides the flow rate of the N₂ gas as mentioned above, further requirements for growing a film are an SiH₄ gas flow rate of 75 (sccm); an H₂ gas flow rate of 52 (sccm); film deposition pressure of 50 (mTorr); and microwave power of 1.3 kW. In the embodiment in FIG. 4, the compressive stress is decreasing as the flow rate of the N₂ gas is decreased from 170 (sccm). The stress can be seen to change from compressive stress to tensile stress in the boundary of a value of 155 (sccm).

This means that the internal stress on the SiNₓ film can be adjusted by regulating the flow ratio of the N₂ gas. Specifically, the SiNₓ film having small internal stress can be grown by means of optimizing the flow ratio of the N₂ gas. FIG. 5 is a view showing an example of an organic EL device whose protective film is formed through use of the film deposition apparatus of the present embodiment, showing a diagrammatic configuration of the organic EL device. Transparent electrodes 42 constituted as anodes, which is serving as the source for supplying positive holes, are formed in a predetermined pattern on the substrate 9 which is formed from the transparent glass substrate. Oxides consisting of indium and tin, which are called ITO (Indium-Tin-Oxide), are generally used for the transparent electrodes 42.

An organic EL layer 43 is provided on the transparent electrodes 42. A metal electrode 44 constituted as a cathode is formed on the organic EL layer 43. A protective film 45 is formed so as to cover the metal electrode 44 and the organic EL layer 43. A lead section 44a of the metal electrode 44 is exposed from the protective film 45. The metal electrode 44 is made of an alloy consisting of magnesium and silver or from aluminum. The metal electrode 44 is functioning as a cathode for supplying electrons.

When a voltage is applied between the electrodes 42, 44, positive holes are implanted from the transparent electrodes 42 to the organic EL layer 43. On the other hand electrons are implanted into the organic EL layer 43 from the metal electrode 44. These implanted positive holes and electrons are coupled again together within the organic EL layer 43. An organic material is excited at the time of re-coupling. Fluorescence is thus generated when the organic material returns from an excited state to a ground state. In order to promote the foregoing reaction, the organic EL layer 43 is generally constituted of a positive hole implantation transport layer, a light-emitting layer, and an electron implantation transport layer.

Since the transparency of the protective film 45 that might be known for related arts has been insufficient. For this reason, a typical organic EL device makes the generated light extracted from the transparent glass substrate 9. However, in the embodiment, the high-density SiNₓ film having high transparency can be taken as the protective film 45 can be produced by using SWP-CVD. Therefore, it enables an organic EL device to be a top emission type where the light is extracted through the protective film 45 as indicated by broken lines in FIG. 5 so that the luminance of the organic EL device can be significantly improved.

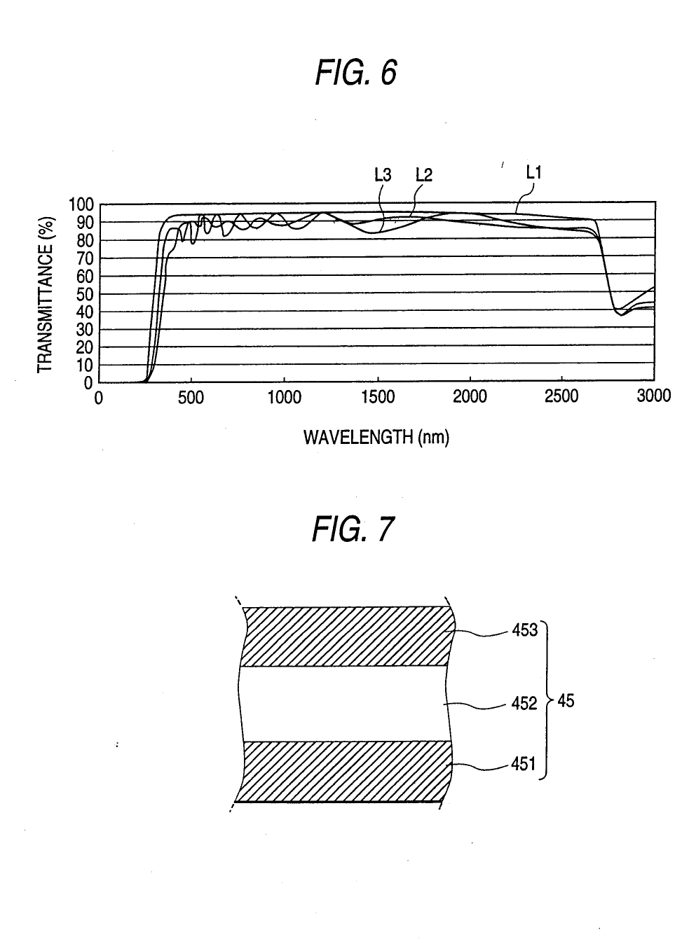

FIG. 6 is a view showing a result of measurement of transparency of the high-density SiNₓ film grown by the SWP-CVD apparatus of the embodiment. In FIG. 6, the vertical axis represents transmittance (%), and the horizontal axis represents the wavelength of light (nm). A curve L1 shows transmittance of a glass substrate before the high-density SiNₓ film is grown on the substrate. Curves L2, L3 show transmittances of grown high-density SiNₓ films. The curves L2, L3 differ from each other in terms of the N₂ gas flow rate. As is evident from FIG. 6, there is achieved a transmittance which is comparable with that of the glass substrate. Since the transmittance does not change much according to a wavelength, the protective film 45 is not deemed as a colored film.

In the embodiment shown in FIG. 5, the protective film 45 is taken as a single layer structure. However, as shown in FIG. 7, the protective film may be formed into a three-layer structure. FIG. 7 is an enlarged cross-sectional view of the protective film 45. The protective film is formed from three layers in a sequence of the organic EL layer; namely, an SiNₓ film 451 having tensile stress, an SiNₓ film 452 having compressive stress, and an SiNₓ film 453 having tensile stress.

The SiNₓ film 452 with compressive stress deposition under the condition of the N₂ gas flow rate is greater than 155 (sccm) in FIG. 4. On the other hand, SiNₓ films 451, 453 with tensile stress are grown under the condition that the N₂ gas flow rate is lower than 155 (sccm). More specifically, at the time of deposition of the SiNₓ film 452, the flow rate of the mass flow controller 18 in FIG. 1 is set to a value of greater than 155 (sccm). At the time of deposition of the SiNₓ films 451, 453, the flow rate of the mass flow controller 18 is set to a value lower than 155 (sccm). Here, said explanation is given by reference to FIG. 4, where a value of 155 (sccm) is taken as the flow rate at which stress changes from compressive stress to tensile stress, however, this value may vary according to the flow rate of another gas.

By means of regulating the flow ratio of the N₂ gas, the film deposition apparatus of the present embodiment realizes the selective deposition of SiNₓ film, having compressive stress layer and tensile stress layer, readily. In other words, a protective film (i.e., an SiNₓ film) having small residual stress can be formed on the organic EL device, by means of stacking alternately SiNₓ film with compressive stress and another SiNₓ film with tensile stress.

In the foregoing description, the SiNₓ films from 451 to 453 are sequentially grown by means of changing the flow rate of the N₂ gas in the single process chamber 3. However, the protective film 45 having a three-layer structure might be also formed, for instance, by using a first SWP-CVD apparatus of which N₂ gas flow rate is set to a value greater than 155 (sccm) and a second SWP-CVD apparatus for which the N₂ gas flow rate is set to a value lower than 155 (sccm). In other words, in case of film deposition of SiNₓ film 452 is transferred into the substrate 9 to the first SWP-CVD apparatus for forming the film, while in case of SiNₓ films 451, 453 the substrate 9 is transferred into to the second SWP-CVD apparatus.

As mentioned above, in the present embodiment, the SiNₓ film having tensile stress and the SiNₓ film having compressive stress are formed alternately to be the stacking layers so as to form the protective film 45. As a result, a residual stress of the protective film 45 can be lowered, and a levitation of the metal electrode 44 or exfoliation of the protective film 45 can be prevented.

The embodiment shown in FIG. 7 has been described by means of taking the three alternate layers as an example. However, the only condition for the protective film 45 is to have a multilayer structure, wherein the SiNₓ film having compressive stress and another SiNₓ film having tensile stress are alternately stacked. For instance, the SiNₓ film 453 shown in FIG. 7 might be omitted, and the protective film 45 might be constituted of the SiNₓ film 451 and the SiNₓ film 452. Further, said protective film might be formed in a reverse sequence order, such as SiNₓ film 452 and SiNₓ film 451, from the organic EL layer 43.

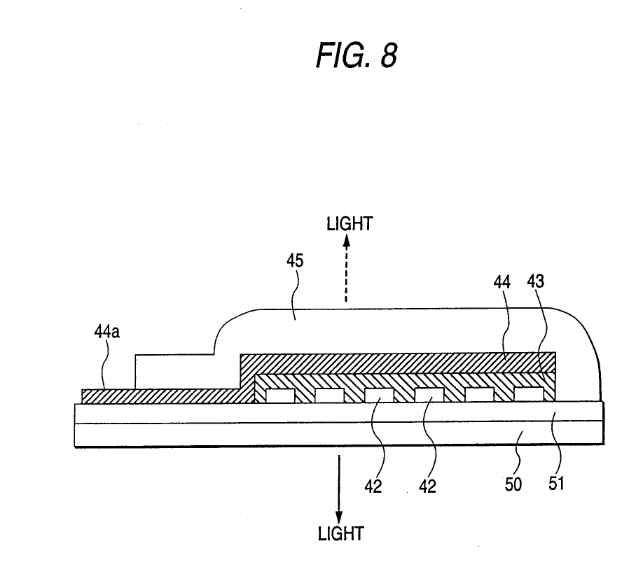

FIG. 8 is a view showing a second embodiment of the organic EL device. In FIG. 8, those devices which are the same as those shown in FIG. 5 are denoted by the same reference numerals, and the following explanation will be focused only on its different aspects. The organic EL device shown in FIG. 5 adopts the glass substrate as the substrate 9. However, in the second embodiment, a transparent resin substrate 50 is used in place of it. When the organic EL device is formed on the transparent resin substrate 50, a high-density SiNₓ film 51 is formed on the transparent resin substrate 50 by using the film deposition apparatus shown in FIG. 1. Constituent devices of the organic EL device, such as the transparent electrode 42, the organic EL layer 43, and the metal electrode 44, are formed on the high-density SiNₓ film 51, and the protective film 45 is formed from a high-density SiNₓ film so as to seal the organic EL layer 43.

The transparent resin substrate 50 does not have enough moisture permeability as compared with the above mentioned glass substrate 9, therefore the high-density SiNₓ film 51 is provided to compensate the moisture permeability of the transparent resin substrate 50. Since the transparency of the high-density SiNₓ film 51 is high, extraction of light might not be affected by the transparent resin substrate 50. Further, the transparent resin substrate 50 is also inferior to the glass substrate 9 in terms of heat resistance, therefore the transparent resin substrate 50 might be deteriorated by a rapid increase of temperature that would arise during formation of the high-density SiNₓ film 51.

However, in the film deposition apparatus of the present embodiment, the transparent resin substrate 50 can be cooled by the He gas by means of causing the He gas to flow through grooves 82 of the cooled substrate holder 8. As a result, said increase of the temperature in the transparent resin substrate 50 can be inhibited beforehand. Therefore, fabrication of the organic EL element can be formed on the transparent resin substrate 50 although it has thermally-inferior characteristic.

In connection with correspondence between the foregoing embodiments, in FIG. 1, microwave generation means is represented by the microwave generation section 1; microwave transmission means by the waveguide 2; cooling means by the cooling holder 8, the chiller 4, and the helium gas source 5; a first supply section by the gas supply pipe 16; a second supply section by the gas supply pipe 17; the first gas by the gas supplied from the gas supply pipe 16; and the second gas by the gas supplied from the gas supply pipe 17. Moreover, the concentration of nitrogen gas corresponding to the N₂ gas flow rate that is greater than 155 (sccm) shown in FIG. 4 corresponds to a first predetermined concentration. The concentration of nitrogen gas corresponding to the N₂ gas flow rate that is lower than 155 (sccm) shown in FIG. 4 corresponds to a second predetermined concentration. Unless the features of the present invention are omitted, the present invention is not limited to these embodiments.

As has been described, according to the invention, the film deposition apparatus employing SWP-CVD is provided with cooling means for cooling a substrate. Hence, a high-density SiNₓ film can be formed as a protective film without causing thermal damage on an organic EL device provided on the substrate.

What is claimed is:

1. A method for manufacturing a protective film for organic EL device, comprising the steps of:
a first film forming step for forming a silicon nitride film with compressive stress being produced therein;
a second film forming step for forming another silicon nitride film with tensile stress being produced therein, and
a protective film forming step for forming protective film by stacking said silicon nitride film and said another silicon nitride film alternately on a substrate, wherein
each film deposition of said silicon nitride film and said another silicon nitride film is performed by a film deposition gas including at least nitrogen where a predetermined concentration of said nitrogen is set to be different from one another.

2. The method for manufacturing a protective film for organic EL device according to claim 1, wherein said film deposition gas is dissociated and excited by using a method of a surface wave plasma CVD (SWP-CVD).

3. A method of depositing a silicon nitride film on an organic EL device provided on a substrate, the method comprising:
generating a microwave;
guiding the microwave to a dielectric-material window of a process chamber so as to radiate the microwave into the process chamber, thereby forming the silicon nitride film on the organic EL device through surface wave plasma (SWP) CVD;
cooling the substrate;
supplying at least one film deposition gas; and
dissociating and exciting the film deposition gas through use of the surface wave plasma generated by the radiation of the microwave into the process chamber.

4. The method according to claim 3, wherein:
the at least one film deposition gas includes first gas which contains at least nitrogen and produces radicals in plasma, and second gas which contains at least silane gas;
the second gas is supplied at a position closer to the substrate than a position that the first gas is supplied.
